(19) United States
(12) Patent Application Publication
(10) Pub. No.: US 2023/0395360 A1
(43) Pub. Date: Dec. 7, 2023

(54) PLASMA PROCESSING APPARATUS, PLASMA PROCESSING METHOD, PRESSURE VALVE CONTROL DEVICE, PRESSURE VALVE CONTROL METHOD, AND PRESSURE REGULATION SYSTEM

(71) Applicant: Tokyo Electron Limited, Tokyo (JP)

(72) Inventors: Kota SHIHOMMATSU, Miyagi (JP); Koki TANAKA, Miyagi (JP); Yuzuru SAKAI, Miyagi (JP); Chishio KOSHIMIZU, Miyagi (JP)

(21) Appl. No.: 18/205,426

(22) Filed: Jun. 2, 2023

(30) Foreign Application Priority Data
Jun. 3, 2022 (JP) 2022-090738
Dec. 26, 2022 (JP) 2022-208742

(51) Int. Cl. H01J 37/32

(52) U.S. Cl. CPC H01J 37/32816; H01J 2237/182; H01J 37/32449; H01J 37/32137

(57) ABSTRACT

Provided is a technique capable of suppressing pressure fluctuations within a plasma processing chamber. A plasma processing apparatus according to the present disclosure includes: a chamber; a gas supply that supplies a processing gas into the chamber; a power supply that generates a source RF signal to form a plasma from the processing gas within the chamber; a storage that stores in advance a source set value that is a set value of a parameter of the source RF signal; a pressure regulation valve connected to the chamber, the pressure regulation valve being configured to regulate an internal pressure of the chamber; an opening degree calculator that calculates an opening degree of the pressure regulation valve, the opening degree being calculated based on the source set value; and an opening degree controller that controls the opening degree of the pressure regulation valve based on the calculated opening degree.

### CROSS-REFERENCE TO RELATED APPLICATIONS

The present application claims priority under 35 U.S.C. § 119 to Japanese Patent Application No. 2022-090738 filed on Jun. 3, 2022 and Japanese Patent Application No. 2022-208742 filed on Dec. 26, 2022, the entire contents of which are incorporated herein by reference.

### BACKGROUND

### Field

Exemplary embodiments of the present disclosure relate to a plasma processing apparatus, a plasma processing method, a pressure valve control device, a pressure valve control method, and a pressure regulation system.

### Description of Related Art

Japanese Patent Application No. 2016-027592 describes a technique for quickly stabilizing a plasma after step switching.

### SUMMARY

The present disclosure provides techniques capable of suppressing pressure fluctuations within a plasma processing chamber.

One exemplary embodiment of the present disclosure provides a plasma processing apparatus. The plasma processing apparatus includes: a chamber; a gas supply that supplies a processing gas into the chamber; a power supply that generates a source RF signal to form a plasma from the processing gas within the chamber; a storage that stores in advance a source set value that is a set value of a parameter of the source RF signal; a pressure regulation valve connected to the chamber, the pressure regulation valve being configured to regulate an internal pressure of the chamber; an opening degree calculator that calculates an opening degree of the pressure regulation valve, the opening degree being calculated based on the source set value; and an opening degree controller that controls the opening degree of the pressure regulation valve based on the calculated opening degree.

### BRIEF DESCRIPTION OF DRAWINGS

FIG. 1 describes a configuration example of a plasma processing system.

FIG. 2 describes a configuration example of a capacity coupled plasma processing apparatus.

FIG. 3 is a block diagram illustrating one example of the configuration of a pressure regulation system 100.

FIG. 4 is a flowchart illustrating the present processing method.

FIG. 5 is an example of a timing chart for each step in the present processing method.

FIG. 6 is a block diagram illustrating one example of the configuration of the pressure regulation system 100.

FIG. 7 is a block diagram illustrating one example of the configuration of the pressure regulation system 100.

### DETAILED DESCRIPTION

The following describes embodiments of the present disclosure.

One exemplary embodiment provides a plasma processing apparatus. The plasma processing apparatus includes: a chamber; a gas supply that supplies a processing gas into the chamber; a power supply that generates a source RF signal to form a plasma from the processing gas within the chamber; a storage that stores in advance a source set value that is a set value of a parameter of the source RF signal; a pressure regulation valve connected to the chamber, the pressure regulation valve being configured to regulate an internal pressure of the chamber; an opening degree calculator that calculates an opening degree of the pressure regulation valve, the opening degree being calculated based on the source set value; and an opening degree controller that controls the opening degree of the pressure regulation valve based on the calculated opening degree.

In one exemplary embodiment, the parameter of the source RF signal includes at least one of power, voltage, frequency and duty ratio of the source RF signal.

One exemplary embodiment further includes a substrate support that supports a substrate in the chamber. In this embodiment, the power supply further generates a bias signal that is supplied to the substrate support, the storage stores a bias set value that is a set value of a parameter of the bias signal, and the opening degree calculator calculates the opening degree of the pressure regulation valve also based on the bias set value stored in the storage.

In one exemplary embodiment, the bias signal is a bias RF signal, and the parameter of the bias signal includes power, voltage, frequency or duty ratio of the bias RF signal.

In one exemplary embodiment, the bias signal is a bias DC signal including a plurality of voltage pulses, and the parameter of the bias signal includes voltage, frequency or duty ratio of the voltage pulses.

In one exemplary embodiment, the storage further stores a flow rate set value that is a set value of a flow rate of the processing gas, and the opening degree calculator calculates the opening degree of the pressure regulation valve also based on the flow rate set value stored in the storage.

One exemplary embodiment further includes a pressure sensor that measures the internal pressure of the chamber. In this embodiment, the opening degree calculator switches, based on an amount of change in the internal pressure of the chamber, from (a) an operation to calculate the opening degree of the pressure regulation valve based on the source set value stored in the storage to (b) an operation to calculate the opening degree of the pressure regulation valve based on the internal pressure of the chamber measured by the pressure sensor.

In one exemplary embodiment, the storage stores gas species included in the processing gas, and the opening degree controller switches whether or not to calculate the opening degree of the pressure regulation valve based on the source set value stored in the storage, based on the gas species stored in the storage.

In one exemplary embodiment, the storage stores a film type included in the substrate that the chamber accommodates, and the opening degree controller switches whether or not to calculate the opening degree of the pressure regulation valve based on the source set value stored in the storage, based on the film type stored in the storage.

In one exemplary embodiment, the substrate that the chamber accommodates includes a mask, the mask having an aperture pattern, the storage stores an aperture ratio of the aperture included in the aperture pattern, and the opening degree controller switches whether or not to calculate the opening degree of the pressure regulation valve based on the source set value stored in the storage, based on the aperture ratio stored in the storage.

In one exemplary embodiment, the storage further stores a transfer function indicative of a relationship between the source set value and the internal pressure of the chamber, and the opening degree calculator calculates the opening degree of the pressure regulation valve also based on the transfer function.

One exemplary embodiment further includes a pressure sensor that measures the internal pressure of the chamber. In this embodiment, the opening degree calculator obtains the internal pressure of the chamber and the opening degree of the pressure regulation valve during execution of the plasma process, and the opening degree calculator updates the transfer function stored in the storage based on correlation between the source set value and the obtained internal pressure of the chamber and opening degree of the pressure regulation valve.

In one exemplary embodiment, the plasma processing apparatus further includes a substrate support that supports a substrate in the chamber; and an upper electrode facing the substrate support. The power supply further generates a DC signal to be applied to the upper electrode, the storage stores a DC set value that is a set value of a parameter of the DC signal, and the opening degree calculator calculates the opening degree of the pressure regulation valve also based on the DC set value stored in the storage.

One exemplary embodiment provides a plasma processing method performed with a plasma processing apparatus having a chamber. The plasma processing method includes: supplying a processing gas into the chamber; generating a source RF signal to form a plasma from the processing gas within the chamber; storing in advance a source set value that is a set value of a parameter of the source RF signal; and calculating an opening degree of the pressure regulation valve configured to regulate an internal pressure of the chamber, the opening degree being calculated based on the source set value.

One exemplary embodiment provides a pressure valve control device that controls an opening degree of a pressure regulation valve connected to a chamber. The pressure valve control device includes: a communication unit configured to receive a source set value that is a set value of a parameter of a source RF signal, the source RF signal forming a plasma in the chamber; an opening degree calculator that calculates the opening degree of the pressure regulation valve, based on the source set value that the communication unit receives; and an opening degree controller that controls the opening degree of the pressure regulation valve based on the calculated opening degree.

In one exemplary embodiment, the pressure valve control device further includes a storage that stores a transfer function that receives the source set value received by the communication unit as an input. The opening degree calculator reads the transfer function stored in the storage and calculates the opening degree of the pressure regulation valve based on the source set value received by the communication unit and the transfer function read from the storage.

In one exemplary embodiment, in response to the communication unit receiving the source set value, the opening degree calculator calculates the opening degree of the pressure regulation valve based on the source set value and the transfer function.

In one exemplary embodiment, the communication unit receives a transfer function that receives the source set value as an input, and the opening degree calculator calculates the opening degree of the pressure regulation valve based on the source set value and the transfer function that the communication unit receives.

In one exemplary embodiment, in response to the communication unit receiving the source set value and the transfer function, the opening degree calculator calculates the opening degree of the pressure regulation valve based on the source set value and the transfer function.

One exemplary embodiment provides a pressure valve control device that controls an opening degree of a pressure regulation valve connected to a chamber. The pressure valve control device includes: a communication unit configured to receive an opening degree of the pressure control valve, the opening degree being calculated based on a source set value, the source set value being a set value of a parameter of a source RF signal, the source RF signal forming a plasma in the chamber; and an opening degree controller that controls the opening degree of the pressure regulation valve based on the received opening degree.

In one exemplary embodiment, the opening degree of the pressure regulation valve is calculated based on the source set value and the transfer function, and the transfer function is indicative of a relationship between the source set value and the internal pressure of the chamber.

One exemplary embodiment provides a pressure valve control method that controls an opening degree of a pressure regulation valve connected to a chamber. The method includes: receiving a source set value that is a set value of a parameter of a source RF signal, the source RF signal forming a plasma in the chamber; calculating the opening degree of the pressure regulation valve based on the received source set value; and controlling the opening degree of the pressure regulation valve based on the calculated opening degree.

One exemplary embodiment provides a pressure valve control method that controls an opening degree of a pressure regulation valve connected to a chamber. The method includes: receiving an opening degree of the pressure control valve, the opening degree being calculated based on a source set value, the source set value being a set value of a parameter of a source RF signal, the source RF signal forming a plasma in the chamber; and controlling the opening degree of the pressure regulation valve based on the received opening degree.

One exemplary embodiment provides a pressure regulation system. The pressure regulation system includes: a pressure regulation valve connected to a chamber; and a pressure valve control device that controls an opening degree of the pressure regulation valve. The pressure valve control device controls the opening degree of the pressure regulation valve connected to the chamber, and includes: a communication unit configured to receive a source set value that is a set value of a parameter of a source RF signal, the source RF signal forming a plasma in the chamber; an opening degree calculator that calculates the opening degree of the pressure regulation valve, based on the source set value that the communication unit receives; and an opening degree controller that controls the opening degree of the pressure regulation valve based on the calculated opening degree.

One exemplary embodiment provides a pressure regulation system. The pressure regulation system includes: a pressure regulation valve connected to a chamber; and a pressure valve control device that controls an opening degree of the pressure regulation valve. The pressure valve control device includes: a communication unit configured to receive a source set value that is a set value of a parameter of a source RF signal, the source RF signal forming a plasma in the chamber; a storage that stores a transfer function that receives the source set value received by the communication unit as an input; an opening degree calculator that reads the transfer function stored in the storage and calculates the opening degree of the pressure regulation valve based on the source set value received by the communication unit and the transfer function read from the storage; and an opening degree controller that controls the opening degree of the pressure regulation valve based on the calculated opening degree.

One exemplary embodiment provides a pressure regulation system. The pressure regulation system includes: a pressure regulation valve connected to a chamber; and a pressure valve control device that controls an opening degree of the pressure regulation valve. The pressure valve control device includes: a communication unit configured to receive an opening degree of the pressure control valve, the opening degree being calculated based on a source set value, the source set value being a set value of a parameter of a source RF signal, the source RF signal forming a plasma in the chamber; and an opening degree controller that controls the opening degree of the pressure regulation valve based on the received opening degree.

The following describes embodiments of the present disclosure in details with reference to the drawings. Like reference numerals designate like elements in the drawings to omit their duplicated descriptions. Unless otherwise specified, positional relationships such as top, bottom, left, and right will be described based on the positional relationships illustrated in the drawings. The accompanying drawings have not necessarily been drawn to scale, and the actual proportions are not limited to the illustrated ones.

### Configuration Example of Plasma Processing System

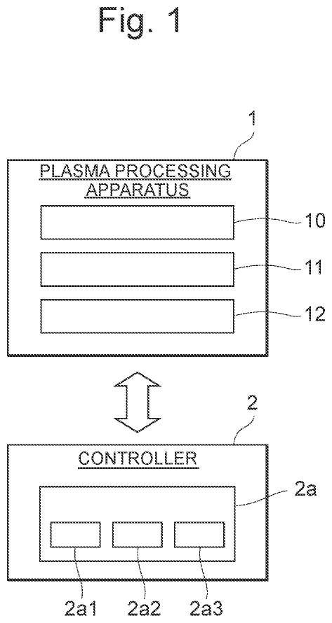

FIG. 1 illustrates a configuration example of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas supply port for supplying at least one processing gas to the plasma processing space and at least one gas exhaust port for exhausting the gas from the plasma processing space. The gas supply port is connected to a gas supply 20, which will be described later, and the gas exhaust port is connected to an exhaust system 40, which will be described later. The substrate support 11 is disposed in the plasma processing space, and has a substrate support face that supports a substrate.

The plasma generator 12 is configured to form a plasma from the at least one processing gas supplied in the plasma processing space. Plasma formed in the plasma processing space includes capacitively coupled plasma (CCP), inductively coupled plasma (ICP), electron-cyclotron-resonance (ECR) plasma, helicon wave plasma (HWP), and surface wave plasma (SWP). Various types of plasma generators may also be used, including alternating current (AC) plasma generators and direct current (DC) plasma generators. In one embodiment, the AC signal (AC power) used in the AC plasma generator has a frequency within the range of 100 kHz to 10 GHz. Thus, AC signals include radio frequency (RF) and microwave signals. In one embodiment, the RF signal has a frequency in the range of 100 kHz to 150 MHz.

The controller (circuitry) 2 processes computer-executable instructions that cause the plasma processing apparatus 1 to perform various steps described in this disclosure. The controller 2 can be configured to control various elements of the plasma processing apparatus 1 to perform various steps described herein. In one embodiment, part or all of the controller 2 may be included in the plasma processing apparatus 1. The controller 2 may include a processor 2a1, a storage 2a2, and a communication interface 2a3. For instance, the controller 2 is implemented by a computer 2a. The processor 2a1 can be configured to read a program from the storage 2a2 and execute the read program to perform various control operations. This program may be stored in the storage 2a2 in advance, or may be acquired via a medium when necessary. The acquired program is stored in the storage 2a2, and the processor 2a1 reads the program from the storage 2a2 for execution. The medium may be various storage media readable by the computer 2a, or may be a communication line connected to the communication interface 2a3. The processor 2a1 may be a central processing unit (CPU). The storage 2a2 may include random access memory (RAM), read only memory (ROM), hard disk drive (HDD), solid state drive (SSD), or a combination of them. The communication interface 2a3 may communicate with the plasma processing apparatus 1 via a communication line such as a local area network (LAN).

### Configuration Example of Plasma Processing Apparatus

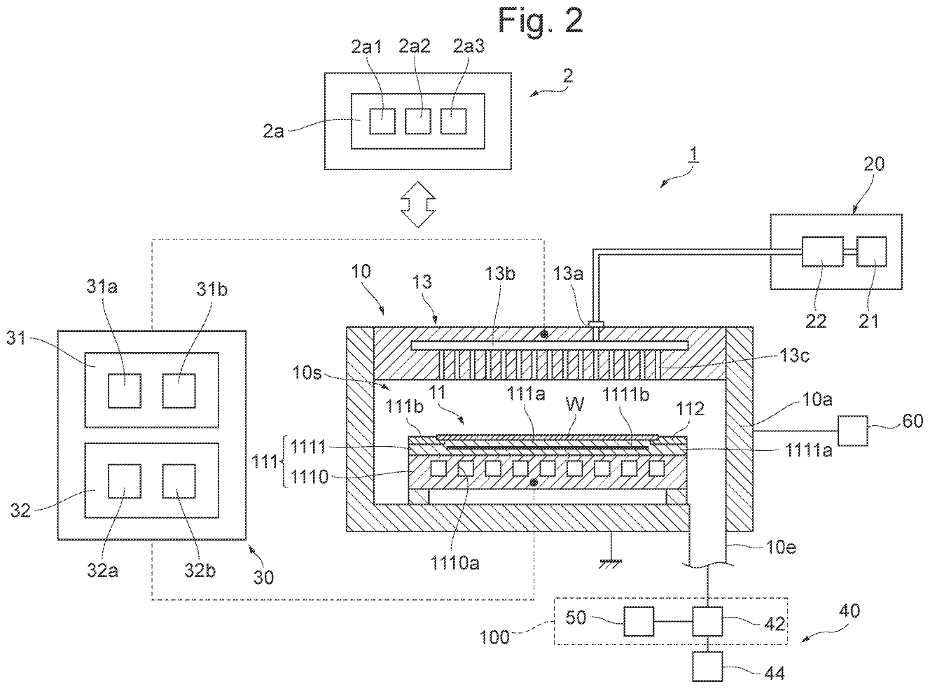

The following describes a configuration example of a capacitively coupled plasma processing apparatus that is one example of the plasma processing apparatus 1. FIG. 2 illustrates a configuration example of a capacity coupled plasma processing apparatus.

The capacity coupled plasma processing apparatus 1 includes a plasma processing chamber 10, a gas supply 20, a power supply 30, and an exhaust system 40. The plasma processing apparatus 1 also includes a substrate support 11, and a gas inlet. The gas inlet is configured to introduce at least one processing gas to the plasma processing chamber 10. The gas inlet includes a showerhead 13. The substrate support 11 is disposed in the plasma processing chamber 10. The showerhead 13 is disposed above the substrate support 11. In one embodiment, the showerhead 13 constitutes at least part of the ceiling of the plasma processing chamber 10. The plasma processing chamber 10 has a plasma processing space defined by the showerhead 13, sidewalls 10a of the plasma processing chamber and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. A wafer is an example of the substrate W. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also referred to as a substrate support face for supporting the substrate W, and the annular region 111b is also referred to as a ring support face for supporting the ring assembly 112.

In one embodiment, the body 111 includes a base 1110 and an electrostatic chuck 1111. The base 1110 includes an electrically conductive member. The electrically conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Note that another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode, which is coupled to a RF power supply 31 and/or a DC power supply 32 described below, may be disposed in the ceramic member 1111a. In this case, the at least one RF/DC electrode functions as a lower electrode. When bias RF and/or DC signals, described below, are supplied to the at least one RF/DC electrode, the RF/DC electrode is also referred to as a bias electrode. Note that the conductive member of the base 1110 and the at least one RF/DC electrode may function as a plurality of lower electrodes. Also, the electrostatic electrode 1111b may function as a lower electrode. Thus, the substrate support 11 includes at least one lower electrode.

The ring assembly 112 includes one or more annular members. In one embodiment, the one or more annular members include one or more edge rings and at least one cover ring. The edge ring(s) is formed from a conductive material or an insulating material, and the cover ring(s) is formed from an insulating material.

The substrate support 11 may include a temperature-controlled module configured to control at least one of the electrostatic chuck 1111, the ring assembly 112, and the substrate to a target temperature. The temperature-controlled module may include a heater, a heat transfer medium, a channel 1110a, or a combination of them. A heat transfer fluid, such as brine or gas, flows through the channel 1110a. In one embodiment, the channel 1110a is formed in the base 1110 and one or more heaters are disposed in the ceramic member 1111a of the electrostatic chuck 1111. The substrate support 11 may include a heat-transfer gas supply configured to supply a heat transfer gas to the gap between the rear face of the substrate W and the central region 111a.

The showerhead 13 is configured to introduce at least one processing gas from the gas supply 20 into the plasma processing space 10s. The showerhead 13 has at least one gas supply port 13a, at least one gas diffuser 13b, and a plurality of gas inlets 13c. The processing gas supplied to the gas supply port 13a passes through the gas diffuser 13b and is introduced into the plasma processing space 10s from the gas inlets 13c. The showerhead 13 also includes at least one upper electrode. In addition to the showerhead 13, the gas inlet may include one or more side gas injectors (SGIs) attached to one or more opening degrees formed in the side walls 10a.

The gas supply 20 may include at least one gas source 21 and at least one flow rate controller 22. In one embodiment, the gas supply 20 is configured to supply at least one processing gas from a corresponding gas source 21 to the showerhead 13 via a corresponding flow rate controller 22. For instance, each flow rate controller 22 may include a mass flow controller or a pressure-controlled flow rate controller. The gas supply 20 also may include at least one flow rate modulation device that modulates or pulses the flow rate of the at least one processing gas.

The power supply 30 includes the RF power supply 31 that is coupled to the plasma processing chamber 10 via at least one impedance matching circuit. The RF power supply 31 is configured to supply at least one RF signal (RF power) to at least one lower electrode and/or at least one upper electrode. This forms a plasma from the at least one processing gas supplied to the plasma processing space 10s. Thus, the RF power supply 31 can function as at least part of the plasma generator 12. A bias RF signal, which is supplied to the at least one lower electrode, generates a bias potential in the substrate W, so that ion components in the formed plasma can be drawn toward the substrate W.

In one embodiment, the RF power supply 31 includes a first RF generator 31a and a second RF generator 31b. The first RF generator 31a is coupled to the at least one lower electrode and/or the at least one upper electrode via at least one impedance matching circuit, and is configured to generate a source RF signal (source RF power) for plasma formation. In one embodiment, the source RF signal has a frequency within the range of 10 MHz to 150 MHz. In one embodiment, the first RF generator 31a may be configured to generate a plurality of source RF signals each having a different frequency. The generated one or more source RF signals are supplied to the at least one lower electrode and/or at least one upper electrode.

The second RF generator 31b is coupled to the at least one lower electrode via at least one impedance matching circuit and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency within the range of 100 kHz to 60 MHz. In one embodiment, the second RF generator 31b may be configured to generate a plurality of bias RF signals each having a different frequency. The generated one or more bias RF signals are supplied to the at least one lower electrode. In various embodiments, at least one of the source RF signal and bias RF signal may be pulsed.

The power supply 30 may also include a DC power supply 32 coupled to the plasma processing chamber 10. The DC power supply 32 includes a first DC generator 32a and a second DC generator 32b. In one embodiment, the first DC generator 32a is connected to the at least one lower electrode and is configured to generate a first DC signal. The generated first DC signal is applied to the at least one lower electrode. In one embodiment, the second DC generator 32b is connected to the at least one upper electrode and is configured to generate a second DC signal. The generated second DC signal is applied to the at least one upper electrode.

In various embodiments, the first and second DC signals may be pulsed. In this case, a sequence of voltage pulses is applied to the at least one lower electrode and/or at least one upper electrode. The voltage pulses may have rectangular, trapezoidal, triangular waveforms or waveforms in a combination of them. In one embodiment, a waveform generator to generate a sequence of voltage pulses from DC signal is connected between the first DC generator 32a and the at least one lower electrode. Thus, the first DC generator 32a and the waveform generator constitute a voltage pulse generator. When the second DC generator 32b and the waveform generator constitute a voltage pulse generator, the voltage pulse generator is connected to the at least one upper electrode. The voltage pulses may have a positive polarity or a negative polarity. The sequence of voltage pulses may include one or more positive voltage pulses or one or more negative voltage pulses in one cycle. The first and second DC generators 32a and 32b may be provided in addition to the RF power supply 31, or the first DC generator 32a may be provided instead of the second RF generator 31b.

For instance, the exhaust system 40 may be connected to a gas exhaust port 10e provided at the bottom of the plasma processing chamber 10. The exhaust system 40 may include a pressure regulation valve 42 and a vacuum pump 44. The pressure regulation valve 42 regulates the pressure in the plasma processing space 10s. In this embodiment, the pressure regulating valve 42 changes the conductance of the pressure regulation valve 42 according to its opening degree. A pressure valve control device 50 may be provided to control the pressure of the plasma processing space 10s by controlling the opening degree of the pressure regulation valve 42. The pressure valve control device 50 may be a part of the plasma processing apparatus 1 or may be an external configuration of the plasma processing apparatus 1. The vacuum pump 44 may include a turbomolecular pump, a dry pump, or a combination of these. At least part of the controller 2, the pressure regulation valve 42 and/or the pressure control device 50 can constitute a pressure regulation system 100.

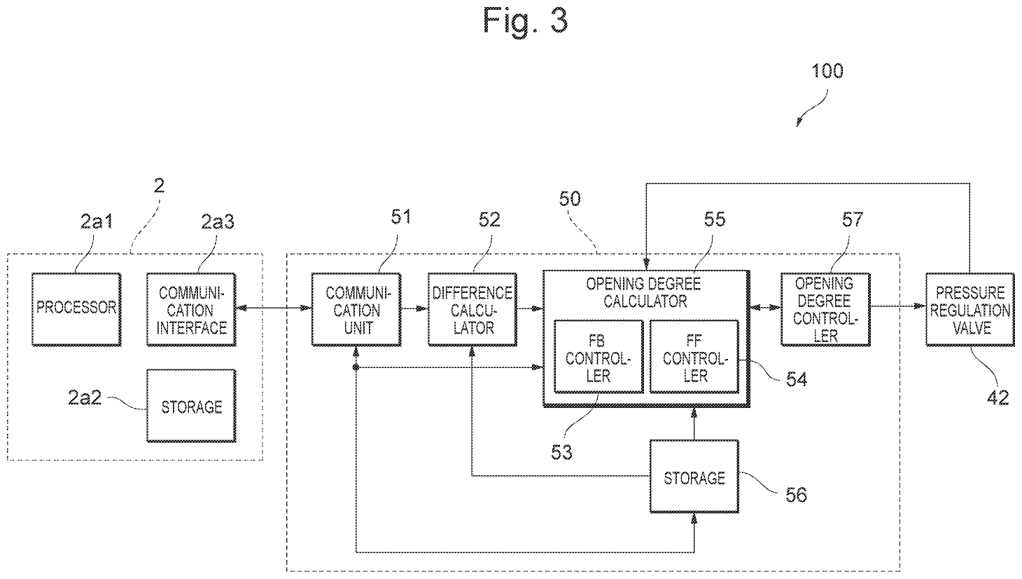

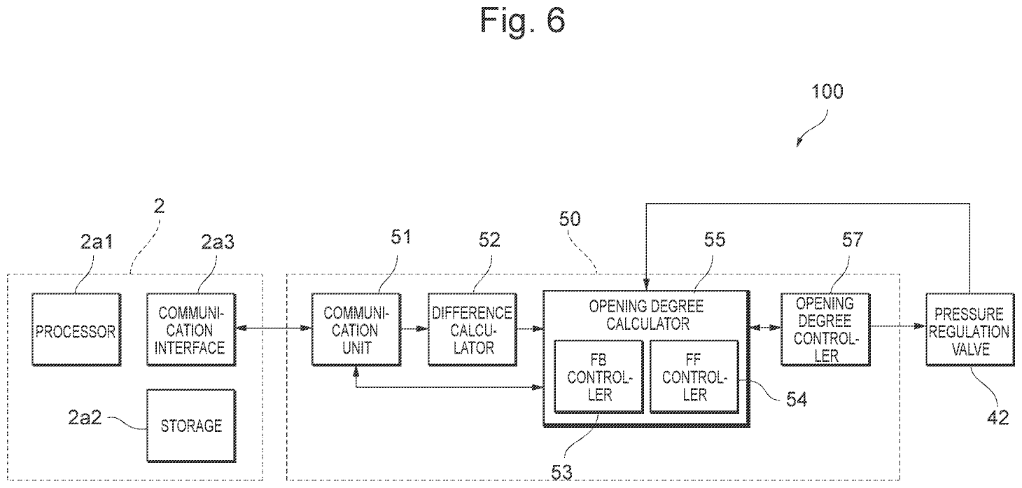

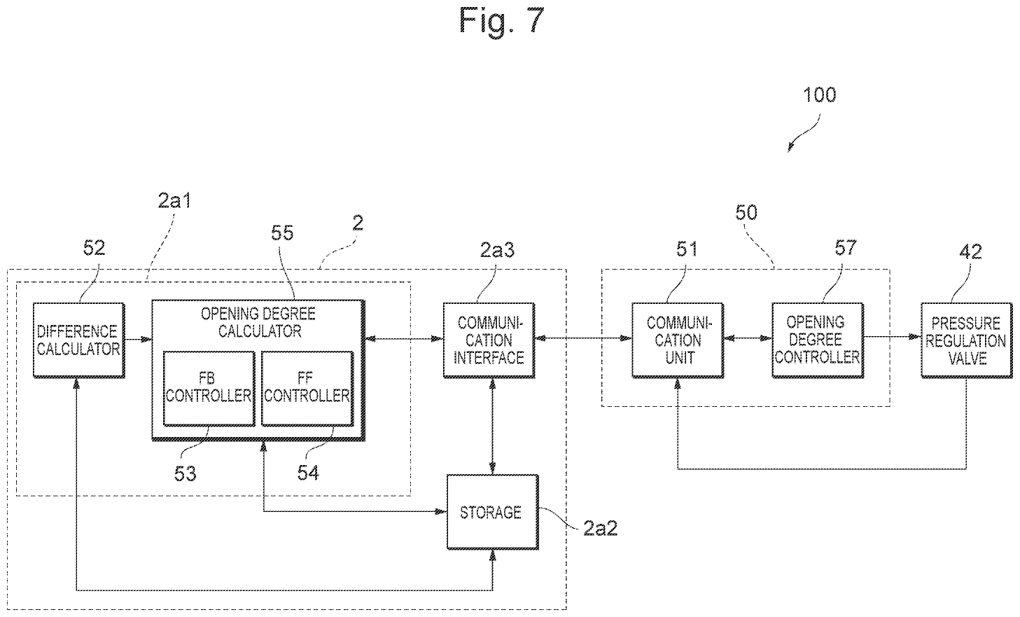

FIG. 3 is a block diagram illustrating one example of the configuration of the pressure regulation system 100. The pressure regulation system 100 can include at least a part of the controller 2, the pressure regulation valve 42, and a pressure regulation device. The pressure valve control device 50 has a communication unit 51, a difference calculator 52, an FB controller 53, an FF controller 54, an opening degree calculator 55, a storage 56, and an opening degree controller 57. Note that the controller 2 may have part or all of the configuration of the pressure valve control device 50. In one embodiment, some or all of the functions executed by the configuration of the pressure valve control device 50 may be performed in the controller 2 (see FIG. 6 and FIG. 7, for example).

The communication unit 51 can be an interface configured to communicate between the pressure valve control device 50 and the controller 2. The communication unit 51 receives control data from the controller 2. The communication unit 51 can communicate with components of the controller 2 via a communication interface 2a3. The communication unit 51 can store part or all of the control data received from the controller 2 in the storage 56. The communication unit 51 can transmit part or all of the control data received from the controller 2 to the opening degree calculator 55.

The communication unit 51 receives measurements of pressure in the plasma processing chamber 10 (hereinafter also referred to as “chamber pressure”) measured by the pressure sensor 60. The communication unit 51 can receive chamber pressure measurements from the pressure sensor 60. The communication unit 51 may receive chamber pressure measurements via the controller 2.

The communication unit 51 can receive opening degree data regarding the opening degree of the pressure regulation valve 42 from the pressure regulation valve 42. The communication unit 51 can transmit the opening degree data to the controller 2. The controller 2 can store the opening degree data received from the communication unit 51 in the storage 2a2. The controller 2 may receive the opening degree data from the pressure regulation valve 42 without via the pressure valve control device 50. The communication unit 51 may store the opening degree data received from the pressure regulation valve 42 in the storage 56. The opening degree data can be the value on an encoder that controls the opening degree of the pressure regulation valve 42. The controller 2 can control the operation timing and/or the operation speed of the pressure regulation valve 42 based on the opening degree data.

The difference calculator 52 calculates a pressure difference, which is a difference between the set value of the chamber pressure and the measured value of the chamber pressure. In one example, the calculator 52 may read the set value of the chamber pressure from the storage 56.

The FB controller 53 calculates an FB correction value for feedback-controlling the chamber pressure. In one example, the FB correction value is a value for correcting the opening degree of the pressure regulation valve 42. The FB controller 53 may calculate the FB correction value based on the pressure difference calculated by the difference calculator 52.

The FF controller 54 calculates an FF correction value for feedforward-controlling the chamber pressure. In one example, the FF correction value is a value for correcting the opening degree of the pressure regulation valve 42. The FF controller 54 may calculate the FF correction value based on the control data received by the communication unit 51 and/or stored in the storage 56.

The opening degree calculator 55 includes the FB controller 53 and the FF controller 54. The opening degree calculator 55 calculates the opening degree of the pressure regulation valve 42 based on the FB correction value and/or the FF correction value. The opening degree calculator 55 then controls the opening degree of the pressure regulation valve 42 based on the calculated opening degree. The FB controller 53 and/or the FF controller 54 may control the opening degree of the pressure regulation valve 42 using the FB correction value and/or the FF correction value as the opening degree. In the present disclosure, the calculation operation by the opening degree controller 55 can be the calculation operation by the FB controller 53 and/or the FF controller 54.

The opening degree calculator 55 can receive opening degree data regarding the opening degree of the pressure regulation valve 42 from the pressure regulation valve 42. The opening degree data can be the value on an encoder that controls the opening degree of the pressure regulation valve 42. The opening degree calculator 55 can control the operation timing and/or the operation speed of the pressure regulation valve 42 based on the opening degree data. The opening degree calculator 55 may store the opening degree data received from the pressure regulation valve 42 in the storage 56.

The storage 56 stores data related to the control of the pressure regulation valve 42. In one embodiment, the data stored in the storage 56 may include part or all of control data described later. In one example, the control data stored in the storage 56 may include a transfer function.

### Example of Plasma Processing Method

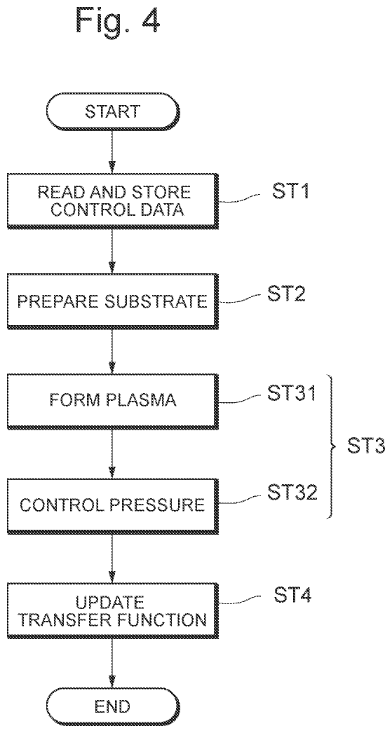

FIG. 4 is a flowchart illustrating a plasma processing method (hereinafter also referred to as “this processing method”) according to one exemplary embodiment. As illustrated in FIG. 4, this processing method includes a step of reading control data (ST1), a step of preparing a substrate (ST2), a step of etching the substrate (ST3), and a step of updating a transfer function (ST4). The processing in each step may be performed with the plasma processing system illustrated in FIG. 1. The following describes an example in which the controller 2 controls each part of the plasma processing apparatus 1, and the pressure valve control device 50 controls the pressure regulation valve 42 in the pressure regulation system 100 illustrated in FIG. 3 to execute this processing method.

(Step ST1: Reading and storing control data)

In step ST1, control data for executing this processing method is read. In one example, part or all of the control data may be read from the storage 2a2 included in the controller 2. Also in step ST1, control data for executing this processing method is stored. In one embodiment, part or all of the control data may be stored in the storage 56 of the pressure valve control device 50.

The control data is to control each part of the plasma processing apparatus 1 to execute this processing method. In one example, the control data may include recipe data and a transfer function. The recipe data may include set values of parameters of the source RF signal in the etching process of step ST3. In one example, the parameters of the source RF signal can include the power, voltage, frequency and duty ratio of the source RF signal, and the duration of the source RF power supply. The recipe data can also include set values of the parameters of the bias signal (bias RF signal and bias DC signal). In one example, the parameters of the bias signal can include the power, voltage, frequency and duty ratio of the bias signal, and the duration of the bias signal supply. The recipe data can also include set values of the second DC signal applied to the upper electrode. In one example, the parameters of the second DC signal can include the voltage of the second DC signal, and the application duration of the second DC signal. The recipe data can include the parameters for processing gas in this etching process. In one example, the parameters of the processing gas can include the flow rate of the processing gas, the gas species contained in the processing gas, the dissociation degree of the gases contained in the processing gas, the type and amount of by-product generated from the gases contained in the processing gas, and the supply duration of the processing gas.

The transfer function is a function that receives set values of one or more parameters included in the recipe data as an input and outputs set values for regulating the pressure in the plasma processing space 10s. In one example, the transfer function can be a function that receives the set values of the parameters of the source RF signal and/or the set values of the parameters of the processing gas as an input, and outputs the opening degree of the pressure regulation valve 42, the correction value of the opening degree or the pressure of the plasma processing space 10s. In one example, the transfer function can include time constant information. For instance, the time constant information can be the time until the internal pressure starts to change when the opening degree of the pressure regulation valve 42 is set to a predetermined opening degree in order to bring the internal pressure of the plasma processing chamber 10 to a predetermined pressure, and the time for the internal pressure to reach the predetermined pressure. The time constant information can be the time from when the gas supply 20 starts supplying the processing gas until the internal pressure of the plasma processing chamber 10 starts to change, and the time until this internal pressure becomes approximately constant. The transfer function may be generated or updated by machine learning.

The transfer function can be a function that models the relationship between the amount of change in multiple parameters and the amount of change in chamber pressure. In one example, the transfer function may be determined as follows. The opening degree of the pressure regulation valve 42 is first fixed, and the values of the parameters are changed. Then database is created based on the relationship between the amounts of change in the parameters and in the chamber pressure. Then, based on the created database, the relationship between the amount of change in the parameters and the amount of change in chamber pressure is modeled. A transfer function is then generated based on the modeled relationship. A transfer function may be prepared for each recipe data.

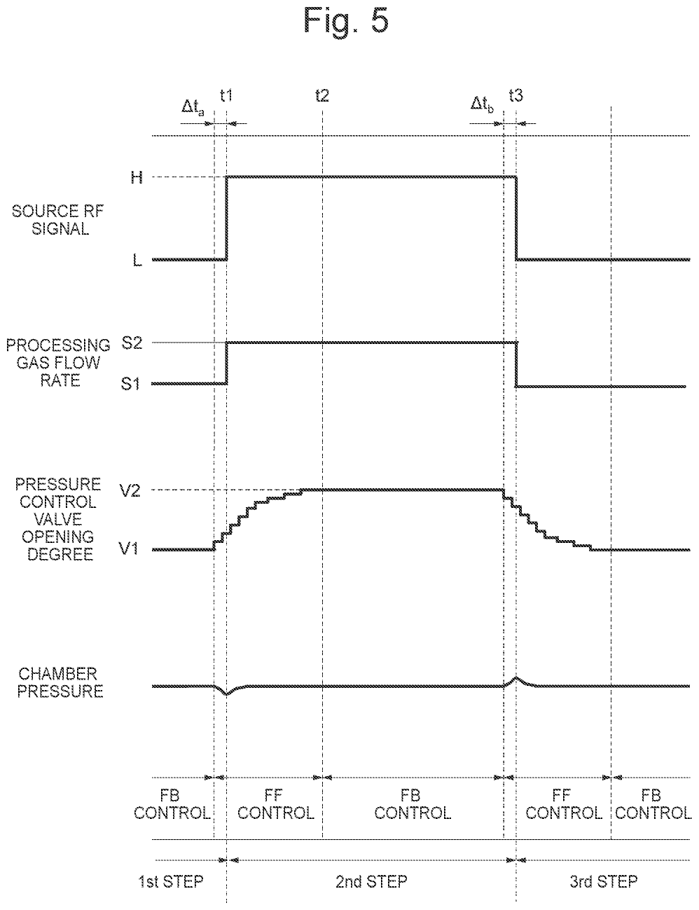

In one example, one transfer function may be associated with one recipe data. In one example, if one recipe data contains a plurality of steps, a different transfer function may be associated with each step. In one example, these steps can be the first to third steps illustrated in FIG. 5. The recipe data and the transfer functions can be associated in advance and stored in the storage 2a2 and/or the storage 56. A transfer function may be read from the storage 2A2 and/or storage 56 based on the corresponding recipe data, thereby associating the transfer function with the recipe data.

In one example, the storage 2a2 stores part or all of the control data, and the processor 2a1 may read the control data from the storage 2a2. The controller 2 may transmit the control data read from the storage 2a2 to the communication unit 51 via the communication interface 2a3. The communication unit 51 can store the control data received from the controller 2 in the storage 56. In one example, the communication unit 51 can transmit the control data received from the controller 2 to the opening degree calculator 55. In one example, the storage 56 stores part or all of the control data, and the FF controller 54 may read the control data from the storage 56.

Reading and/or storing part or all of the control data in step ST1 can be performed any time. In one example, the reading and/or storing of control data can be performed prior to the execution of step ST3 (step of etching the substrate). In one example, the reading and/or storing of part of the control data can be performed at different timing from the reading and/or storing another part of the control data. In the configuration example illustrated in FIG. 3, one or more transfer functions can be read from the storage 2a2 and stored in the storage 56, and then the recipe data can be read from the storage 2a2 and transmitted from the controller 2 to the communication unit 51. In the configuration example illustrated in FIG. 3, reading and storing the transfer function can be performed prior to step ST2, and reading and storing the recipe data can be performed after step ST2.

In one example, each of the components of the pressure control device may read control data and other data from the storage 2a2 via the communication unit 51, instead of from the storage 56. In this case, as illustrated in FIG. 6, the pressure valve control device 50 does not need to have the storage 56 that stores the control data 50 in advance. In the example illustrated in FIG. 6, the pressure valve control device 50 may have a configuration for buffering or temporarily storing the control data and other data received by the communication unit 51.

(Step ST2: Substrate preparation) In step ST2, the substrate W is prepared in the plasma processing space 10s of the plasma processing apparatus 1. Specifically, the substrate W is held on the substrate support 11 by the electrostatic chuck 1111. The substrate W may be a substrate used in the manufacture of semiconductor devices. The substrate W includes an etching film and a mask film. The etching film is to be etched in this processing method. In this processing method, the etching film is etched by the plasma formed in the plasma processing space 10s, using the mask film as a mask.

(Step ST3: Substrate Etching)

In step ST3, the substrate W is etched. Step ST3 includes a step of forming a plasma (ST31) and a step of controlling the pressure in the plasma processing space 10s (ST32). Step ST31 can include a step of supplying a processing gas into the plasma processing chamber 10, a step of supplying a source RF signal, and a step of supplying a bias RF signal. In each of these steps, a plasma containing active species is formed from the processing gas, and the etching film is etched by the active species. These processing gas, source RF signal, and bias signal may start to be supplied in any order. In step ST32, the pressure in the plasma processing space 10s is controlled. The plasma formation in step ST31 and the pressure control in step ST32 can be executed in parallel. Referring to FIG. 4 and FIG. 5, the following describes the details of step ST3.

FIG. 5 is an example of a timing chart for each step in this processing method. In the timing chart of FIG. 5, the horizontal axis indicates time, and the vertical axis indicates the value (relative value) of each parameter.

In step ST31, a plasma is formed in the plasma processing space 10s. The controller 2 controls the plasma generator 12 based on the recipe data read in step ST1 to form a plasma in the plasma processing space 10s. Meanwhile, in the pressure valve control device 50, the opening degree calculator 55 reads one or more transfer functions from the storage 56 based on the recipe data received from the controller 2 via the communication unit 51. In the configuration example illustrated in FIG. 3, one or more transfer functions may be stored in the storage 56 before the communication unit 51 receives the recipe data from the controller 2. The opening degree calculator 55 calculates the opening degree of the pressure regulation valve 42 based on the recipe data and the transfer function. The opening degree controller 57 controls the opening degree of the pressure regulation valve 42 based on the calculated opening degree.

In the example illustrated in FIG. 5, the etching step ST3 includes a first step and a second step. In one example, the recipe data includes the frequency, power and duty ratio of the source RF signal at each step. The recipe data also includes the gas species contained in the processing gas and the flow rate of the processing gas in each step.

In the example illustrated in FIG. 5, the source RF signal is a pulsed wave that periodically includes pulses composed of RF. That is, the source RF signal is a pulse wave that periodically repeats a period when the effective value of the source RF power (hereinafter simply referred to as “power”) is L and a period when the power is H. In the first step, the source RF signal is L in power. In the second step, the source RF signal is H in power. The power H is greater than the power L. The magnitude of the source RF power, the frequency of the pulse wave, and the RF frequency making up the pulse wave may be set appropriately based on the etching process to be performed. In one example, the power L may be 0 W. The duty ratio of the source RF signal may be set appropriately based on the etching process to be performed. The duty ratio is the ratio of the period of high power to the period of low power in one cycle of the pulse wave of the source RF signal. For instance, in the second step illustrated in FIG. 5, the duty ratio is the ratio of the period during which the source RF power is H to the period during which it is L in one cycle of the pulse wave of the source RF signal.

In step ST31, the controller 2 can control the first RF generator 31a (see FIG. 2) included in the power supply 30 to generate the source RF signal. The controller 2 also can control the second RF generator 31b (see FIG. 2) included in the power supply 30 to generate the bias RF signal. In one example, a plasma may be formed in the plasma processing chamber 10 by the RF signal generated by the second RF generator 31b. That is, the RF signal generated by the second RF generator 31b can also function as the “source RF signal” in the present disclosure.

In the first step, the controller 2 controls the gas supply 20 based on the recipe data read from the storage 2a2 to supply the processing gas into the plasma processing chamber 10 at the flow rate S2. The controller 2 controls the RF power supply 31 based on the read recipe data, generates the above-described pulse wave as a source RF signal, and supplies it to the substrate support 11. This forms a plasma from the processing gas in the plasma processing space 10s, thus etching the substrate W. The controller 2 may control the RF power supply 31 based on the recipe data to generate a bias RF signal or a bias DC signal, and supply the bias RF signal or the bias DC signal to the substrate support 11.

In the first step, the pressure valve control device 50 controls the opening degree of the pressure regulation valve 42 to control the chamber pressure (step ST32). The pressure valve control device 50 may control the opening degree of the pressure regulation valve 42 by feed-forward control (hereinafter referred to as “FF control”) based on the recipe data received by the communication unit 51. In one example, the FF controller 54 in the opening degree calculator 55 may calculate the opening degree of the pressure regulation valve 42 based on the source set value received by the communication unit 51 and the transfer function read from the storage 56. The source set value can be the set value of the parameters of the source RF signal. In the opening degree calculation unit 55, when the communication unit 51 receives the source set value, which is the set value of the parameter of the source RF signal, the FF controller 54 can calculate the opening degree of the pressure regulation valve 42 based on the source set value received by the communication unit 51 and the transfer function that receives the source set value as an input. The transfer function that receives the source set value as an input may be read from the storage 56 based on the source set value. The transfer function can be a function indicative of the relationship between the source set value and chamber pressure.

The pressure valve control device 50 may control the opening degree of the pressure regulation valve 42 by feedback control (hereinafter referred to as “FB control”) based on the chamber pressure measured by the pressure sensor. In this processing method, each step begins with the pressure valve control device 50 controlling the opening degree of the pressure regulation valve 42 by FF control. After the chamber pressure reaches a steady state, the pressure valve control device 50 controls the opening degree of the pressure regulation valve 42 by FB control. FB control is performed based on the actually measured chamber pressure. In the first step in FIG. 5, the opening degree of the pressure regulation valve 42 is approximately constant at the opening degree V1, and the chamber pressure is at a steady state.

The etching process performed in etching step ST3 transitions from the first step to the second step at time t1 (see FIG. 5). When the etching process transitions from the first step to the second step, the controller 2 controls the gas supply 20 based on the recipe data to change the flow rate of the processing gas from flow rate S1 to flow rate S2. The controller 2 also changes the source RF signal from a pulse wave with power L to a pulse wave with power H based on the recipe data. As the flow rate of the processing gas supplied to the plasma processing chamber 10 increases, the chamber pressure can increase. As the source RF power increases, the chamber pressure can increase because the amount of processing gas dissociated in the plasma processing space 10s increases. The amount of dissociation of the processing gas in the plasma processing space 10s can also vary depending on the gas species contained in the processing gas.

The pressure valve control device 50 controls the opening degree of the pressure regulation valve 42 based on changes in the parameters of the source RF signal as well as gas species and/or change in flow rate contained in the processing gas at time t1. This can suppress fluctuations in the chamber pressure. At this time, the pressure valve control device 50 changes the control of the opening degree of the pressure regulation valve 42 from FB control to FF control to control the chamber pressure. Specifically, first, the FF controller 54 of the pressure valve control device calculates the FF correction value that corrects the opening degree of the pressure regulating valve 42 based on the recipe data that the communication unit 51 receives from the controller 2 and the transfer function read from the storage 56. This transfer function may be a transfer function associated with the second step included in the recipe data that the communication unit 51 receives from the controller 2. Then, the opening degree calculator 55 calculates the opening degree of the pressure regulation valve 42 based on the FF correction value calculated by the FF controller 54 and adjusts the opening degree of the pressure regulation valve 42. Here, the transfer function can be a function that receives the parameters of the source RF signal, the gas species included in the processing gas, and/or the flow rate of each of the gas species as an input, and outputs the opening degree of the pressure regulation valve 42. The parameters of the source RF signal can include the power, frequency and duty ratio of the source RF signal. The FF control may be started before time t1. In the example illustrated in FIG. 5, the FF control starts at a time earlier than time t1 by Δtₐ. The storage 56 stores in advance a film to be etched and/or a film type that serves as a mask included in the substrate W, and the pressure regulation system 100 may perform the FF control based on these film types stored in advance. The transfer function can be a function further based on the aperture ratio in the aperture pattern of the mask. The chamber pressure can also vary depending on the film to be etched and/or the type of film used as a mask that are included in the substrate W. The chamber pressure also can vary depending on the aperture ratio of the mask included in the substrate W.

In one example, FF control is executed based on various set values included in the recipe data. These set values may include a set value of the power of the source RF signal, a set value of the frequency of the source RF signal, a set value of the duty ratio of the source RF signal, a set value of the flow rate of the processing gas, and a set value of the amount of change in flow rate of the processing gas. The amount of change in flow rate of the processing gas may be an absolute amount of change, or may be an amount of change per unit time. In one example, FF control may be performed based on the parameter set values of the bias RF signal and/or bias DC signal included in the recipe data. For instance, the controller 2 may perform the control based on the effective value and frequency of the power of the bias RF signal or the voltage of the bias DC signal. If the bias DC signal includes a sequence of voltage pulses, FF control may be performed based on the frequency and/or duty ratio of the sequence of voltage pulses.

When the pressure regulation valve 42 is FF-controlled based on the recipe data and the chamber pressure reaches a steady state, the pressure valve control device 50 (or opening degree calculator 55) changes the control of the pressure regulation valve 42 from FF control to FB control. In the example illustrated in FIG. 5, the pressure valve control device 50 switches the pressure regulation valve 42 to FB control at time t2 when it is determined that the opening degree of the pressure regulation valve 42 has become substantially constant at the opening degree V2 and the chamber pressure has reached a steady state. In one example, the controller 2 may determine that the chamber pressure has reached a steady state when the amount of change in chamber pressure over a predetermined period of time or the amount of change in chamber pressure over a unit of time is below a predetermined value. In one example, the pressure valve control device 50 may determine that the chamber pressure has reached a steady state when the amount of change (absolute amount) in opening degree of the pressure regulation valve 42 over a predetermined period of time or the amount of change in opening degree of the pressure regulation valve 42 over a unit of time is below a predetermined value. After time t2, the pressure valve control device 50 controls the opening degree of the pressure regulation valve 42 based on the chamber pressure measured by the pressure sensor. In one example, the communication unit 51 may receive the measurements of the chamber pressure from the controller 2 or the pressure sensor. The difference calculator 52 calculates a pressure difference, which is a difference between the set value of the chamber pressure and the measured value of the chamber pressure. The FB controller 53 receives the pressure difference from the difference calculator 52, and calculates an FB correction value for correcting the opening degree of the pressure regulation valve 42, based on the pressure difference. Then, the opening degree calculator 55 calculates the opening degree of the pressure regulation valve 42 based on the FB correction value and adjusts the opening degree of the pressure regulation valve 42.

The etching process performed in etching step ST3 transitions from the second step to the third step at time t3 (see FIG. 5). In this example, when the etching process transitions from the second step to the third step, the controller 2 controls the gas supply 20 based on the recipe data to change the flow rate of the processing gas from flow rate S2 to flow rate S1. The controller 2 also changes the source RF signal from a pulse wave with power H to a pulse wave with power L based on the recipe data. As the flow rate of the processing gas supplied to the plasma processing chamber 10 decreases, the chamber pressure can decrease. As the source RF power decreases, the chamber pressure can decrease because the amount of processing gas dissociated in the plasma processing space 10s decreases.

The pressure valve control device 50 controls the opening degree of the pressure regulation valve 42 based on changes in the parameters of the source RF signal as well as gas species contained in the processing gas and/or change in flow rate of each of the gas species at time t3. This can suppress fluctuations in the chamber pressure. At this time, in the same manner as when the second step started at time t1, the pressure valve control device 50 changes the control of the opening degree of the pressure regulation valve 42 from FB control to FF control to control the chamber pressure. Specifically, first, the FF controller 54 of the pressure valve control device 50 calculates the FF correction value that corrects the opening degree of the pressure regulating valve 42 based on the recipe data that the communication unit 51 receives from the controller 2 and the transfer function read from the storage 56. The transfer function may be a transfer function associated with the third step included in the recipe data that the communication unit 51 receives from the controller 2. The FF controller 54 may adjust the time to start changing the opening degree of the pressure regulation valve 42 based on the transfer function. Then, the opening degree calculator 55 calculates the opening degree of the pressure regulation valve 42 based on the FF correction value calculated by the FF controller 54 and adjusts the opening degree of the pressure regulation valve 42. The FF control may be started before time t3. In the example illustrated in FIG. 5, the FF control starts at a time earlier than time t3 by Atb.

When the pressure regulation valve 42 is FF-controlled based on the recipe data and the chamber pressure reaches a steady state, the pressure valve control device 50 (or opening degree calculator 55) changes the control of the pressure regulation valve 42 from FF control to FB control, as in the second step. In the example illustrated in FIG. 5, the pressure valve control device 50 switches the pressure regulation valve 42 to FB control at time t2 when it is determined that the opening degree of the pressure regulation valve 42 has become substantially constant at the opening degree V1 and the chamber pressure has reached a steady state. When the processing by each step specified in the recipe data is executed, the controller 2 stops supplying the source RF signal and the processing gas. This completes step ST3.

In this processing method, the pressure regulation valve 42 is FF-controlled based on the parameters of the source RF signal and other set values included in the recipe data. This suppresses fluctuations in the chamber pressure, even if the set values of the parameter change in the recipe data during the plasma processing. Note that the chamber pressure may fluctuate due to various factors during the execution of this processing method. This processing method can suppress chamber pressure fluctuations based on changes in set values included in the recipe data. In each of the configuration examples illustrated in FIGS. 3, 6 and 7, the controller 2 or pressure valve control device 50 may perform FF control and FB control simultaneously.

(Step ST4: Update transfer function)

The processing method may include step ST4 of updating the transfer function used in step ST3. In one example, the transfer function may be updated based on the chamber pressure and the opening degree of the pressure regulation valve 42 in step ST3. For example, the controller 2 measures the chamber pressure and the opening degree of the pressure regulation valve 42 during the execution of the FF control in step ST3. The controller 2 then may calculate the correlation data between the parameters and other set values of the source RF signal included in the recipe data and/or the parameters and other measured values of the source RF signal, and the measured values of the chamber pressure and the measured values of the opening degree of the pressure regulation valve 42, and may update the transfer function stored in the storage 2a2 based on the correlation data. In one example, the other set values and measured values can include the set values and measured values of the parameters of the bias signal (bias RF signal and bias DC signal), the set values and measured values of the second DC signal applied to the upper electrode, the set values and measured values of the parameters of the processing gas supplied in step ST3, and the set values and measured values of the parameters of the processing gas. The transfer function may be updated based on multiple pieces of correlation data calculated by performing the processing method multiple times. The transfer function may be updated by machine learning. The transfer function may be updated in real time during the execution of step ST3 based on the correlation data calculated during the execution of step ST3.

FIG. 6 is a block diagram illustrating another example of the configuration of the pressure regulation system 100. The pressure regulation system 100 in this example differs from the pressure regulation system 100 in FIG. 3 at least in that the recipe data and the transfer function are stored in advance in the storage 2a2. That is, the opening degree calculator 55 in this example can read one or more transfer functions based on the recipe data received by the communication unit 51 not from the storage 56 (see FIG. 3) but from the storage 2a2 via the communication unit 51. In this example, the controller 2 may transmit the recipe data and one or more transfer functions to the opening degree calculator 55 via the communication unit 51. That is, in this example, the transfer function used in the opening degree calculator 55 may be selected by the controller 2 or may be selected by the opening degree calculator 55.

In one example, the communication unit 51 receives a source set value, which are set values of the parameters of the source RF signal, and a transfer function. The opening degree calculator 55 calculates the opening degree of the pressure regulation valve 42 based on the source set value and transfer function received by the communication unit 51. The source set value can be the set values of the parameters of the source RF signal. When the communication unit 51 receives the source set value, which is the set values of the parameters of the source RF signal, and the transfer function that receives the source set value as an input, the opening degree calculator 55 may calculate the opening degree of the pressure regulation valve 42 based on the source set value and the transfer function.

The recipe data may include set values (source set values) of parameters of the source RF signal in the etching process of step ST3. In one example, the parameters of the source RF signal can include the power, voltage, frequency and duty ratio of the source RF signal, and the duration of the source RF power supply. The recipe data can also include set values of the parameters of the bias signal (bias RF signal and bias DC signal). In one example, the parameters of the bias signal can include the power, voltage, frequency and duty ratio of the bias signal, and the duration of the bias signal supply. The recipe data can also include set values of the second DC signal applied to the upper electrode. In one example, the parameters of the second DC signal can include the voltage of the second DC signal, and the application duration of the second DC signal. The recipe data can include the parameters for processing gas in this etching process. In one example, the parameters of the processing gas can include the flow rate of the processing gas, the gas species contained in the processing gas, the dissociation degree of the gases contained in the processing gas, the type and amount of by-product generated from the gases contained in the processing gas, and the supply duration of the processing gas.

The transfer function is a function that receives set values for one or more parameters included in the recipe data as an input and outputs set values for adjusting the pressure in the plasma processing space 10s. In one example, the transfer function can be a function that receives the set values of the parameters of the source RF signal and/or the set values of the parameters of the processing gas as an input, and outputs the opening degree of the pressure regulation valve 42, the correction value of the opening degree or the pressure of the plasma processing space 10s. In one example, the transfer function can include time constant information. For instance, the time constant information can be the time until the internal pressure starts to change when the opening degree degree of the pressure regulation valve 42 is set to a predetermined opening degree degree in order to bring the internal pressure of the plasma processing chamber 10 to a predetermined pressure, and the time for the internal pressure to reach the predetermined pressure. The time constant information can be the time from when the gas supply 20 starts supplying the processing gas until the internal pressure of the plasma processing chamber 10 starts to change, and the time until this internal pressure becomes approximately constant. The transfer function may be generated or updated by machine learning.

In this example, the pressure valve control device 50 may have a configuration for buffering or temporarily storing the control data and other data received by the communication unit 51. In one example, the recipe data and transfer function read from the controller 2a2 can be buffered or temporarily stored in the pressure valve control device 50. The recipe data and transfer function may be buffered or temporarily stored in the pressure valve control device 50 to allow the FF controller 54 to calculate the FF correction value.

In this example, the controller 2 can control the plasma processing apparatus 1 as in the example illustrated in FIG. 3. In this example, each of the components of the pressure regulation system 100 can operate similarly to the example illustrated in FIG. 3. The storage 2a2 can store similar data to the storage 2a2 and the storage 56 in the example illustrated in FIG. 3. In the pressure valve control device 50, the opening degree calculator 55 can calculate the opening degree of the pressure regulation valve 42, as in the example illustrated in FIG. 3.

FIG. 7 is a block diagram illustrating another example of the configuration of the pressure regulation system 100. The pressure regulation system 100 in this example differs from the pressure regulation system 100 in FIG. 3 at least in that the controller 2 is equipped with a function to calculate the opening degree of the pressure regulation valve 42. That is, the controller 2 in this example includes a difference calculator 52 and an opening degree calculator 55 in the processor 2a1. The pressure control device 50 in this example has a communication unit 51 and an opening degree controller 57.

In this example, the controller 2 can control the plasma processing apparatus 1 as in the example illustrated in FIG. 3. In this example, each of the components of the pressure regulation system 100 can operate similarly to the example illustrated in FIG. 3. The storage 2a2 can store similar data to the storage 2a2 and the storage 56 in the example illustrated in FIG. 3. In the controller 2, the opening degree calculator 55 can calculate the opening degree of the pressure regulation valve 42, as in the example illustrated in FIG. 3. That is, in this example, the opening degree calculator 55 reads the recipe data and transfer function from the storage 2a2, and can calculate the opening degree of the pressure regulation valve 42 based on the read recipe data and transfer function. In the pressure control device 50, the communication unit 51 receives the opening degree of the pressure regulation valve 42 from the controller 2 via the communication interface 2a3. The opening degree controller 57 controls the opening degree of the pressure regulation valve 42 based on the received opening degree.

The opening degree received by communication unit 51 can be calculated in the opening degree calculator 55 based on the source set value. The source set value can be the set value of the parameters of the source RF signal. The source RF signal can be a signal to form a plasma in the plasma processing chamber 10. The opening degree calculator 55 may read the source set value, which is the set value of the parameters of the source RF signal, from the storage 2a2. Based on the source set value read from the storage 2a2, the opening degree calculator 55 may read from the storage 2a2 a transfer function that receives the source set value as the input. The opening degree calculator 55 can calculate the opening degree of the pressure regulation valve 42 based on the source set value and transfer function read from the storage 2a2. The transfer function can be a function indicative of the relationship between the source set value and chamber pressure.

The recipe data may include set values (source set values) of parameters of the source RF signal in the etching process of step ST3. In one example, the parameters of the source RF signal can include the power, voltage, frequency and duty ratio of the source RF signal, and the duration of the source RF power supply. The recipe data can also include set values of the parameters of the bias signal (bias RF signal and bias DC signal). In one example, the parameters of the bias signal can include the power, voltage, frequency and duty ratio of the bias signal, and the duration of the bias signal supply. The recipe data can also include set values of the second DC signal applied to the upper electrode. In one example, the parameters of the second DC signal can include the voltage of the second DC signal, and the application duration of the second DC signal. The recipe data can include the parameters for processing gas in this etching process. In one example, the parameters of the processing gas can include the flow rate of the processing gas, the gas species contained in the processing gas, the dissociation degree of the gases contained in the processing gas, the type and amount of by-product generated from the gases contained in the processing gas, and the supply duration of the processing gas.

The transfer function is a function that receives set values of one or more parameters included in the recipe data as an input and outputs set values for adjusting the pressure in the plasma processing space 10s. In one example, the transfer function can be a function that receives the set value of the parameters of the source RF signal and/or the set value of the parameters of the processing gas as an input, and outputs the opening degree of the pressure regulation valve 42, the correction value of the opening degree or the pressure of the plasma processing space 10s. In one example, the transfer function can include time constant information. For instance, the time constant information can be the time until the internal pressure starts to change when the opening degree degree of the pressure regulation valve 42 is set to a predetermined opening degree degree in order to bring the internal pressure of the plasma processing chamber 10 to a predetermined pressure, and the time for the internal pressure to reach the predetermined pressure. The time constant information can be the time from when the gas supply 20 starts supplying the processing gas until the internal pressure of the plasma processing chamber 10 starts to change, and the time until this internal pressure becomes approximately constant. The transfer function may be generated or updated by machine learning.

The communication unit 51 can receive opening degree data regarding the opening degree of the pressure regulation valve 42 from the pressure regulation valve 42. The communication unit 51 can transmit the opening degree data to the controller 2. The controller 2 can store the opening degree data received from the communication unit 51 in the storage 2a2. The controller 2 may receive the opening degree data from the pressure regulation valve 42 without via the pressure valve control device 50. The communication unit 51 may store the opening degree data received from the pressure regulation valve 42 in the storage 56. The opening degree data can be the value of an encoder that controls the opening degree of the pressure regulation valve 42. The controller 2 can control the operation timing and/or the operation speed of the pressure regulation valve 42 based on the opening degree data.

One exemplary embodiment of the present disclosure provides techniques capable of suppressing pressure fluctuations within a plasma processing chamber.

The embodiments disclosed here are to be considered in all respects as illustrative and not restrictive. The embodiments described above may be omitted, substituted, or modified in various ways without departing from the scope and spirit of the appended claims. Exemplary embodiments of the present disclosure may include the followings.

(Addendum 1)

A plasma processing apparatus including: a chamber;
a gas supply that supplies a processing gas into the chamber;
a power supply that generates a source RF signal to form a plasma from the processing gas within the chamber;
a storage that stores in advance a source set value that is a set value of a parameter of the source RF signal; a pressure regulation valve connected to the chamber, the pressure regulation valve being configured to regulate an internal pressure of the chamber;
an opening degree calculator that calculates an opening degree of the pressure regulation valve, the opening degree being calculated based on the source set value; and
an opening degree controller that controls the opening degree of the pressure regulation valve based on the calculated opening degree.

(Addendum 2)

The plasma processing apparatus according to addendum 1, wherein the parameter of the source RF signal includes at least one of power, voltage, frequency and duty ratio of the source RF signal.

(Addendum 3)

The plasma processing apparatus according to addendum 1 or 2 further including a substrate support that supports a substrate in the chamber; wherein
the power supply further generates a bias signal that is supplied to the substrate support,
the storage stores a bias set value that is a set value of a parameter of the bias signal, and
the opening degree calculator calculates the opening degree of the pressure regulation valve also based on the bias set value stored in the storage.

(Addendum 4)

The plasma processing apparatus according to addendum 3, wherein the bias signal is a bias RF signal, and
the parameter of the bias signal includes power, voltage, frequency or duty ratio of the bias RF signal.

(Addendum 5)

The plasma processing apparatus according to addendum 3, wherein the bias signal is a bias DC signal including a plurality of voltage pulses, and
the parameter of the bias signal includes voltage, frequency or duty ratio of the voltage pulses.

(Addendum 6)

The plasma processing apparatus according to any one of addenda 1 to 5, wherein the storage further stores a flow rate set value that is a set value of a flow rate of the processing gas, and
the opening degree calculator calculates the opening degree of the pressure regulation valve also based on the flow rate set value stored in the storage.

(Addendum 7)

The plasma processing apparatus according to any one of addenda 1 to 6 further including a pressure sensor that measures the internal pressure of the chamber, wherein
the opening degree calculator switches, based on an amount of change in the internal pressure of the chamber, from (a) an operation to calculate the opening degree of the pressure regulation valve based on the source set value stored in the storage to (b) an operation to calculate the opening degree of the pressure regulation valve based on the internal pressure of the chamber measured by the pressure sensor.

(Addendum 8)

The plasma processing apparatus according to any one of addenda 1 to 7, wherein the storage stores gas species included in the processing gas, and
the opening degree controller switches whether or not to calculate the opening degree of the pressure regulation valve based on the source set value stored in the storage, based on the gas species stored in the storage.

(Addendum 9)

The plasma processing apparatus according to any one of addenda 1 to 8, wherein the storage stores a film type included in the substrate that the chamber accommodates, and
the opening degree controller switches whether or not to calculate the opening degree of the pressure regulation valve based on the source set value stored in the storage, based on the film type stored in the storage.

(Addendum 10)

The plasma processing apparatus according to any one of addenda 1 to 9, wherein the substrate that the chamber accommodates includes a mask, the mask having an aperture pattern,
the storage stores an aperture ratio of the aperture included in the aperture pattern, and
the opening degree controller switches whether or not to calculate the opening degree of the pressure regulation valve based on the source set value stored in the storage, based on the aperture ratio stored in the storage.

(Addendum 11)

The plasma processing apparatus according to any one of addendum 1 to 10, wherein the storage further stores a transfer function indicative of a relationship between the source set value and the internal pressure of the chamber, and
the opening degree calculator calculates the opening degree of the pressure regulation valve also based on the transfer function.

(Addendum 12)

The plasma processing apparatus according to addendum 11 further including a pressure sensor that measures the internal pressure of the chamber, wherein
the opening degree calculator obtains the internal pressure of the chamber and the opening degree of the pressure regulation valve during execution of the plasma process, and
the opening degree calculator updates the transfer function stored in the storage based on correlation between the source set value and the obtained internal pressure of the chamber and opening degree of the pressure regulation valve.

(Addendum 13)

The plasma processing apparatus according to any one of addenda 1 or 12 further including a substrate support that supports a substrate in the chamber; and an upper electrode facing the substrate support, wherein
the power supply further generates a DC signal to be applied to the upper electrode,
the storage stores a DC set value that is a set value of a parameter of the DC signal, and
the opening degree calculator calculates the opening degree of the pressure regulation valve also based on the DC set value stored in the storage.

(Addendum 14)

A plasma processing method performed with a plasma processing apparatus having a chamber, including:
supplying a processing gas into the chamber;
generating a source RF signal to form a plasma from the processing gas within the chamber;
storing in advance a source set value that is a set value of a parameter of the source RF signal; and
calculating an opening degree of the pressure regulation valve configured to regulate an internal pressure of the chamber, the opening degree being calculated based on the source set value.

(Addendum 15)

A pressure valve control device that controls an opening degree of a pressure regulation valve connected to a chamber, including:
a communication unit configured to receive a source set value that is a set value of a parameter of a source RF signal, the source RF signal forming a plasma in the chamber;
an opening degree calculator that calculates an opening degree of the pressure regulation valve, based on the source set value that the communication unit receives; and
an opening degree controller that controls the opening degree of the pressure regulation valve based on the calculated opening degree.

(Addendum 16)

The pressure valve control device according to addendum 15, further including a storage that stores a transfer function that receives the source set value received by the communication unit as an input, wherein
the opening degree calculator reads the transfer function stored in the storage and calculates the opening degree of the pressure regulation valve based on the source set value received by the communication unit and the transfer function read from the storage.

(Addendum 17)

The pressure valve control device according to addendum 16, wherein in response to the communication unit receiving the source set value, the opening degree calculator calculates the opening degree of the pressure regulation valve based on the source set value and the transfer function.

(Addendum 18)

The pressure valve control device according to addendum 15, wherein the communication unit receives a transfer function that receives the source set value as an input, and
the opening degree calculator calculates the opening degree of the pressure regulation valve based on the source set value and the transfer function that the communication unit receives.

(Addendum 19)

The pressure valve control device according to addendum 18, wherein in response to the communication unit receiving the source set value and the transfer function, the opening degree calculator calculates the opening degree of the pressure regulation valve based on the source set value and the transfer function.

(Addendum 20)

A pressure valve control device that controls an opening degree of a pressure regulation valve connected to a chamber, including:
a communication unit configured to receive an opening degree of the pressure control valve, the opening degree being calculated based on a source set value, the source set value being a set value of a parameter of a source RF signal, the source RF signal forming a plasma in the chamber; and
an opening degree controller that controls the opening degree of the pressure regulation valve based on the received opening degree.

(Addendum 21)

The pressure valve control device according to addendum 20, wherein the opening degree of the pressure regulation valve is calculated based on the source set value and the transfer function, and the transfer function is indicative of a relationship between the source set value and the internal pressure of the chamber.

(Addendum 22)

A pressure valve control method that controls an opening degree of a pressure regulation valve connected to a chamber, including:
receiving a source set value that is a set value of a parameter of a source RF signal, the source RF signal forming a plasma in the chamber;
calculating the opening degree of the pressure regulation valve based on the received source set value; and
controlling the opening degree of the pressure regulation valve based on the calculated opening degree.

(Addendum 23)

A pressure valve control method that controls an opening degree of a pressure regulation valve connected to a chamber, including:
receiving an opening degree of the pressure control valve, the opening degree being calculated based on a source set value, the source set value being a set value of a parameter of a source RF signal, the source RF signal forming a plasma in the chamber; and
controlling the opening degree of the pressure regulation valve based on the received opening degree.

(Addendum 24)

A pressure regulation system including: a pressure regulation valve connected to a chamber; and
a pressure valve control device that controls an opening degree of the pressure regulation valve, the pressure valve control device controlling the opening degree of the pressure regulation valve connected to the chamber; the pressure valve control device including:
a communication unit configured to receive a source set value that is a set value of a parameter of a source RF signal, the source RF signal forming a plasma in the chamber;
an opening degree calculator that calculates the opening degree of the pressure regulation valve, based on the source set value that the communication unit receives; and
an opening degree controller that controls the opening degree of the pressure regulation valve based on the calculated opening degree.

(Addendum 25)

A pressure regulation system including: a pressure regulation valve connected to a chamber; and
a pressure valve control device that controls an opening degree of the pressure regulation valve,
the pressure valve control device including:
a communication unit configured to receive a source set value that is a set value of a parameter of a source RF signal, the source RF signal forming a plasma in the chamber;
a storage that stores a transfer function that receives the source set value received by the communication unit as an input;
an opening degree calculator that reads the transfer function stored in the storage and calculates the opening degree of the pressure regulation valve based on the source set value received by the communication unit and the transfer function read from the storage; and
an opening degree controller that controls the opening degree of the pressure regulation valve based on the calculated opening degree.

(Addendum 26)

A pressure regulation system including: a pressure regulation valve connected to a chamber; and
a pressure valve control device that controls an opening degree of the pressure regulation valve,
the pressure valve control device including:
a communication unit configured to receive an opening degree of the pressure control valve, the opening degree being calculated based on a source set value, the source set value being a set value of a parameter of a source RF signal, the source RF signal forming a plasma in the chamber; and
an opening degree controller that controls the opening degree of the pressure regulation valve based on the received opening degree.

What is claimed is:

1. A plasma processing apparatus comprising:
a chamber;
a gas supply that supplies a processing gas into the chamber;
a power supply that generates a source RF signal to form a plasma from the processing gas within the chamber;
a storage that stores in advance a source set value that is a set value of a parameter of the source RF signal;
a pressure regulation valve connected to the chamber, the pressure regulation valve being configured to regulate an internal pressure of the chamber;
an opening degree calculator that calculates an opening degree of the pressure regulation valve, the opening degree being calculated based on the source set value; and
an opening degree controller that controls the opening degree of the pressure regulation valve based on the calculated opening degree.

2. The plasma processing apparatus according to claim 1, wherein the parameter of the source RF signal includes at least one of power, voltage, frequency and duty ratio of the source RF signal.

3. The plasma processing apparatus according to claim 1 further comprising a substrate support that supports a substrate in the chamber; wherein
the power supply further generates a bias signal that is supplied to the substrate support,
the storage stores a bias set value that is a set value of a parameter of the bias signal, and
the opening degree calculator calculates the opening degree of the pressure regulation valve also based on the bias set value stored in the storage.

4. The plasma processing apparatus according to claim 3, wherein the bias signal is a bias RF signal, and
the parameter of the bias signal includes power, voltage, frequency or duty ratio of the bias RF signal.

5. The plasma processing apparatus according to claim 3, wherein the bias signal is a bias DC signal including a plurality of voltage pulses, and
the parameter of the bias signal includes voltage, frequency or duty ratio of the voltage pulses.

6. The plasma processing apparatus according to claim 1, wherein the storage further stores a flow rate set value that is a set value of a flow rate of the processing gas, and
the opening degree calculator calculates the opening degree of the pressure regulation valve also based on the flow rate set value stored in the storage.

7. The plasma processing apparatus according to claim 1 further comprising a pressure sensor that measures the internal pressure of the chamber, wherein
the opening degree calculator switches, based on an amount of change in the internal pressure of the chamber, from (a) an operation to calculate the opening degree of the pressure regulation valve based on the source set value stored in the storage to (b) an operation to calculate the opening degree of the pressure regulation valve based on the internal pressure of the chamber measured by the pressure sensor.

8. The plasma processing apparatus according to claim 1, wherein the storage stores gas species included in the processing gas, and
the opening degree controller switches whether or not to calculate the opening degree of the pressure regulation valve based on the source set value stored in the storage, based on the gas species stored in the storage.

9. The plasma processing apparatus according to claim 1, wherein the storage stores a film type included in the substrate that the chamber accommodates, and
the opening degree controller switches whether or not to calculate the opening degree of the pressure regulation valve based on the source set value stored in the storage, based on the film type stored in the storage.

10. The plasma processing apparatus according to claim 1, wherein the substrate that the chamber accommodates includes a mask, the mask having an aperture pattern,
the storage stores an aperture ratio of the aperture included in the aperture pattern, and
the opening degree controller switches whether or not to calculate the opening degree of the pressure regulation valve based on the source set value stored in the storage, based on the aperture ratio stored in the storage.

11. The plasma processing apparatus according to claim 1, wherein the storage further stores a transfer function indicative of a relationship between the source set value and the internal pressure of the chamber, and
the opening degree calculator calculates the opening degree of the pressure regulation valve also based on the transfer function.

12. The plasma processing apparatus according to claim 11 further comprising a pressure sensor that measures the internal pressure of the chamber, wherein
the opening degree calculator obtains the internal pressure of the chamber and the opening degree of the pressure regulation valve during execution of the plasma process, and
the opening degree calculator updates the transfer function stored in the storage based on correlation between the source set value and the obtained internal pressure of the chamber and opening degree of the pressure regulation valve.

13. The plasma processing apparatus according to claim 1 further comprising: a substrate support that supports a substrate in the chamber; and
an upper electrode facing the substrate support, wherein
the power supply further generates a DC signal to be applied to the upper electrode,
the storage stores a DC set value that is a set value of a parameter of the DC signal, and
the opening degree calculator calculates the opening degree of the pressure regulation valve also based on the DC set value stored in the storage.

14. A plasma processing method performed with a plasma processing apparatus having a chamber, comprising:
supplying a processing gas into the chamber;
generating a source RF signal to form a plasma from the processing gas within the chamber;
storing in advance a source set value that is a set value of a parameter of the source RF signal; and
calculating an opening degree of the pressure regulation valve, the pressure regulation valve being configured to regulate an internal pressure of the chamber, the opening degree being calculated based on the source set value.

15. A pressure valve control device that controls an opening degree of a pressure regulation valve connected to a chamber, comprising:
a communication unit configured to receive a source set value that is a set value of a parameter of a source RF signal, the source RF signal forming a plasma in the chamber;
an opening degree calculator that calculates the opening degree of the pressure regulation valve, based on the source set value that the communication unit receives; and
an opening degree controller that controls the opening degree of the pressure regulation valve based on the calculated opening degree.

16. The pressure valve control device according to claim 15, further comprising a storage that stores a transfer function that receives the source set value received by the communication unit as an input, wherein
the opening degree calculator reads the transfer function stored in the storage and calculates the opening degree of the pressure regulation valve based on the source set value received by the communication unit and the transfer function read from the storage.

17. The pressure valve control device according to claim 16, wherein in response to the communication unit receiving the source set value, the opening degree calculator calculates the opening degree of the pressure regulation valve based on the source set value and the transfer function.

18. The pressure valve control device according to claim 15, wherein the communication unit receives a transfer function that receives the source set value as an input, and
the opening degree calculator calculates the opening degree of the pressure regulation valve based on the source set value and the transfer function that the communication unit receives.

19. The pressure valve control device according to claim 18, wherein in response to the communication unit receiving the source set value and the transfer function, the opening degree calculator calculates the opening degree of the pressure regulation valve based on the source set value and the transfer function.

20. A pressure valve control device that controls an opening degree of a pressure regulation valve connected to a chamber, comprising:
a communication unit configured to receive an opening degree of the pressure control valve, the opening degree being calculated based on a source set value, the source set value being a set value of a parameter of a source RF signal, the source RF signal forming a plasma in the chamber; and
an opening degree controller that controls the opening degree of the pressure regulation valve based on the received opening degree.

21. The pressure valve control device according to claim 20, wherein the opening degree of the pressure regulation valve is calculated based on the source set value and the transfer function, and the transfer function is indicative of a relationship between the source set value and the internal pressure of the chamber.

22. A pressure valve control method that controls an opening degree of a pressure regulation valve connected to a chamber, comprising:
receiving a source set value that is a set value of a parameter of a source RF signal, the source RF signal forming a plasma in the chamber;
calculating the opening degree of the pressure regulation valve based on the received source set value; and
controlling the opening degree of the pressure regulation valve based on the calculated opening degree.

23. A pressure valve control method that controls an opening degree of a pressure regulation valve connected to a chamber, comprising:
receiving an opening degree of the pressure control valve, the opening degree being calculated based on a source set value, the source set value being a set value of a parameter of a source RF signal, the source RF signal forming a plasma in the chamber; and
controlling the opening degree of the pressure regulation valve based on the received opening degree.

24. A pressure regulation system comprising:
a pressure regulation valve connected to a chamber; and
a pressure valve control device that controls an opening degree of the pressure regulation valve, the pressure valve control device controlling the opening degree of the pressure regulation valve connected to the chamber, the pressure valve control device including:
a communication unit configured to receive a source set value that is a set value of a parameter of a source RF signal, the source RF signal forming a plasma in the chamber;
an opening degree calculator that calculates the opening degree of the pressure regulation valve, based on the source set value that the communication unit receives; and
an opening degree controller that controls the opening degree of the pressure regulation valve based on the calculated opening degree.

25. A pressure regulation system comprising: a pressure regulation valve connected to a chamber; and
a pressure valve control device that controls an opening degree of the pressure regulation valve,
the pressure valve control device including:
a communication unit configured to receive a source set value that is a set value of a parameter of a source RF signal, the source RF signal forming a plasma in the chamber;
a storage that stores a transfer function that receives the source set value received by the communication unit as an input;
an opening degree calculator that reads the transfer function stored in the storage and calculates the opening degree of the pressure regulation valve based on the source set value received by the communication unit and the transfer function read from the storage; and
an opening degree controller that controls the opening degree of the pressure regulation valve based on the calculated opening degree.

26. A pressure regulation system comprising: a pressure regulation valve connected to a chamber; and
a pressure valve control device that controls an opening degree of the pressure regulation valve,
the pressure valve control device including:
a communication unit configured to receive an opening degree of the pressure control valve, the opening degree being calculated based on a source set value, the source set value being a set value of a parameter of a source RF signal, the source RF signal forming a plasma in the chamber; and
an opening degree controller that controls the opening degree of the pressure regulation valve based on the received opening degree.
